(19) United States
(12) Patent Application Publication
(10) Pub. No.: US 2023/0202743 A1
(43) Pub. Date: Jun. 29, 2023

(54) INNER RETICLE POD COVER AND BASEPLATE SHIPPER

(71) Applicant: ENTEGRIS, INC., Billerica, MA (US)

(72) Inventors: Anthony Mathius Tieben, Belle Plaine, MN (US); Philip Stuart Glynn, Colorado Springs, CO (US); Russ V. Raschke, Chanhassen, MN (US)

(21) Appl. No.: 18/090,714

(22) Filed: Dec. 29, 2022

Related U.S. Application Data
(60) Provisional application No. 63/294,463, filed on Dec. 29, 2021.

(51) Int. Cl. B65D 85/48; B65D 6/00; B65B 5/04

(52) U.S. Cl. CPC B65D 85/48; B65D 11/10; B65B 5/04

(57) ABSTRACT

Shipping containers for covers or baseplates of reticle pods include a first shell including first fixing features and a second shell including second fixing features. When the first shell and the second shell are joined, the shells define an internal space capable of accommodating a cover or a baseplate of a reticle pod, and the fixing features engage the cover or baseplate to prevent movement of the cover or baseplate in directions in plane with the first or second shells. The fixing features can be such that there are both rigid and elastic fixing features contacting the cover or baseplate. A method of storing a cover or baseplate can include placing the cover or baseplate between first and second shells and joining the first and second shells to one another.

### FIELD

This disclosure is directed to shipping containers for covers and/or baseplates used as the inner pod of a reticle pod.

### PRIORITY

This disclosure claims priority to U.S. provisional patent application No. 63/294,463 with a filing date of Dec. 29, 2021, which is incorporated by reference herein.

### BACKGROUND

Reticles to be processed, for example through photolithography such as extreme ultraviolet (EUV) can be stored and conveyed in reticle pods including an outer pod and an inner pod. The inner pod can include a baseplate and a cover.

### SUMMARY

This disclosure is directed to shipping containers for covers and/or baseplates used as the inner pod of a reticle pod.

Shipping containers according to embodiments can protect the covers and/or baseplates of reticle inner pods during shipping to users of the covers and baseplates. This can reduce the incidence of damage to the covers and/or baseplates, thus reducing or preventing loss of usable covers and baseplates during transit. In embodiments, the shipping containers can increase the number of covers and/or baseplates that can be shipped in a given volume of shipping space. The shipping containers can use opposing rigid and hard retention points to both firmly secure the covers and/or baseplates while reducing the effect of shocks on the covers and/or baseplates. Shipping containers according to embodiments can be configured to interface with features already present in the design of the covers and/or baseplates such that the covers and/or baseplates can be secured in the shipping containers without further modification of the covers and/or baseplates.

A container for a cover or a baseplate of a reticle pod includes a first shell comprising a plurality of first fixing features and a second shell comprising a plurality of second fixing features. The first shell and the second shell are configured to be joined together. When the first shell and the second shell are joined together, the first shell and the second shell define an interior space. The interior space is sized such that it can accommodate the cover or the baseplate of the reticle pod. The first fixing features are configured to engage the cover or the baseplate of the reticle pod at first predetermined positions corresponding to first pod features provided on a first side of the cover or the baseplate of the reticle pod. The second fixing features are configured to engage the cover or the baseplate of the reticle pod at second predetermined positions corresponding to second pod features provided on a second side of the cover or the baseplate of the reticle pod. When the first fixing features engage with the first pod features and the second fixing features engage with the second pod features, the engagement restricts movement of the cover or the baseplate of the reticle pod in plane with at least one of the first shell or the second shell.

In an embodiment, at least one of the first fixing features or the second fixing features each include a resilient material. In an embodiment, the resilient material is a fluoroelastomer.

In an embodiment, at least one of the first fixing features or the second fixing features each include a rigid material. In an embodiment, the rigid material is a same material as a body of the first shell or the second shell.

In an embodiment, the container is for the cover of the reticle pod and at least some of the first predetermined positions and the second predetermined positions correspond to through holes of the cover of the reticle pod.

In an embodiment, the container is for the baseplate of the reticle pod and at least one of the first predetermined positions or the second predetermined positions corresponds to a kinematic coupling groove of the baseplate of the reticle pod.

In an embodiment, the first predetermined positions and the second predetermined positions correspond to non-functional locations of the cover or the baseplate of the reticle pod.

In an embodiment, the first shell and the second shell each include polycarbonate or a polyolefin.

In an embodiment, a method of storing a cover or a baseplate of a reticle pod includes placing the cover or the baseplate of the reticle pod into a first shell of a container. The first shell including a plurality of first fixing features. Placing the cover or the baseplate of the reticle pod into the first shell includes engaging first pod features on a first side of the cover or the baseplate with the plurality of first fixing features. The method further includes joining a second shell of the container to the first shell of the container. The second shell includes second engagement features. Joining the second shell of the container to the first shell includes engaging second pod features on a second side of the cover or the baseplate with the second fixing features. The engagement of the first fixing features with the first pod features and the engagement of the second fixing features with the second pod features restrict movement of the cover or the baseplate of the reticle pod in plane with at least one of the first shell or the second shell.

In an embodiment, at least one of the first fixing features or the second fixing features each include a resilient material. In an embodiment, the resilient material is a fluoroelastomer.

In an embodiment, at least one of the first fixing features or the second fixing features each include a rigid material. In an embodiment, the rigid material is a same material as a body of the first shell or the second shell.

In an embodiment, the cover or the baseplate being stored is the cover of the reticle pod and at least some of the first fixing features and the second fixing features engage with through holes formed in the cover of the reticle pod.

In an embodiment, the cover or the baseplate being stored is the baseplate of the reticle pod and at least some of the first fixing features and the second fixing features engage with a kinematic coupling groove of the baseplate of the reticle pod.

In an embodiment, the first fixing features and the second fixing features engage with non-functional locations of the cover or the baseplate of the reticle pod.

In an embodiment, the first shell and the second shell each include polycarbonate or a polyolefin.

### DRAWINGS

FIG. 1 shows a container for a cover or a baseplate of a reticle pod according to an embodiment.

FIG. 2A shows a first side of a baseplate of a reticle pod to be stored in a container according to an embodiment.

FIG. 2B shows a first shell configured to be used on the first side of the baseplate of FIG. 2A.

FIG. 2C shows a second side of the baseplate shown in FIG. 2A

FIG. 2D shows a second shell configured to be used on the second side of the baseplate of FIG. 2C.

FIG. 3A shows a first side of a cover of a reticle pod to be stored in a container according to an embodiment.

FIG. 3B shows a first shell configured to be used on the first side of the cover of FIG. 3A.

FIG. 3C shows a second side of the cover shown in FIG. 3A

FIG. 3D shows a second shell configured to be used on the second side of the cover of FIG. 3C.

FIG. 4 shows a flowchart of a method according to an embodiment.

FIG. 5 shows an interface of contacts of a container with a reticle being contained.

FIG. 6 shows another interface of contacts of a container with a reticle being contained.

FIG. 7 shows another interface of contacts of a container with a reticle being contained.

FIG. 8 shows another interface of contacts of a container with a reticle being contained.

FIG. 9 shows another interface of contacts of a container with a reticle being contained.

### DETAILED DESCRIPTION

This disclosure is directed to shipping containers for covers and/or baseplates used as the inner pod of a reticle pod.

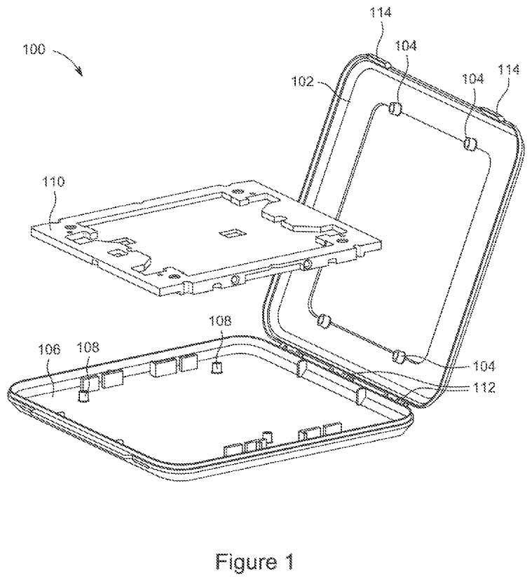

FIG. 1 shows a container for a cover or a baseplate of a reticle pod according to an embodiment. Container 100 includes first shell 102, with a plurality of first contacts 104 provided on first shell 102. Container 100 also includes second shell 106, with a plurality of second contacts 108 provided on the second shell 106. Container 100 can be used to contain a cover or baseplate 110 of a reticle pod.

Container 100 is configured to contain a cover or baseplate 110. Container 100 is configured to accommodate the cover or baseplate 110 in an internal space defined by the container 100. Container 100 can be used for the storage and/or transportation of the cover or baseplate 110 stored within. In an embodiment, cover or baseplate 110 to be contained in container 100 is a cover of a reticle pod inner pod.

First shell 102 and second shell 106 each include respective fixing features. The fixing features are features provided on each shell 102, 106 that are configured to mechanically engage cover or baseplate 110 when it is inside container 100. The mechanical engagement of the fixing features with the cover or baseplate 110 retains the cover or baseplate in a certain position within container 100, limiting or preventing movement of the cover or baseplate 110. In an embodiment, the engagement of the fixing features limits or prevents movement of the cover or baseplate 110 relative to the first shell 102 and/or second shell 106 including a component in plane with the first shell 102 and/or second shell 106. In the embodiment shown in FIG. 1, first contacts 104 are the fixing features of first shell 102 and second contacts 108 are the fixing features of second shell 106. The fixing features can be any suitable features of the first shell 102 and second shell 106 capable of engaging cover or baseplate 110 so as to limit or prevent its movement within container 100. Non-limiting embodiments of fixing features are shown in FIGS. 5-9 and described below.

First shell 102 forms a portion of container 100. First shell 102 is configured to partially define an interior space such that cover or baseplate 110 can be retained within the internal space. First shell 102 includes a plurality of first contacts 104. In an embodiment, first shell 102 is formed of a polymer material. In an embodiment, first shell 102 is formed of polycarbonate, a polyolefin, or an acrylonitrile butadiene styrene (ABS) polymer. First shell 102 can include first contacts 104 formed on a side of first shell 102 configured to face the cover or baseplate 110 when the cover or baseplate 110 is stored within container 100 as fixing features. The first contacts 104 are provided on first shell 102 in positions corresponding to positions on the cover or baseplate 110 that are to be contacted to retain the cover or baseplate 110 within container 100. The first contacts 104 can be provided in positions corresponding to non-critical positions on the cover or baseplate 110. Non-critical positions on the cover or baseplate 110 are areas where incidental damage during storage or transportation does not materially affect the function of the reticle pod including cover or baseplate 110. Critical areas of the cover or baseplate 110 can include sealing surfaces, high-polish areas, areas of visible plating on the surfaces, areas within the internal space where cover or baseplate 110 will contain a reticle, or the like. Non-critical areas of the cover or baseplate 110 can include corners and sides of the cover or baseplate 110, through holes formed in cover or baseplate 110, safety catch holes, kinematic coupling (KC) grooves, and the like.

The first contacts 104 can include material of the first shell 102. In an embodiment, the first contacts 104 can further include a resilient component, for example where the first contacts 104 would interface with the cover or baseplate 110. Then resilient component can be any suitable resilient material, such as, for example, one or more elastomers. In an embodiment, the resilient component is a thermoplastic elastomer. In an embodiment, the resilient component is a fluoroelastomer. The resilient component can be made of a cross-linked polymer material. Non-limiting examples of materials that can be used in the resilient component include fluorine rubbers such as FKM or Viton™. In an embodiment, the first contacts 104 are provide one of the resilient material or a rigid material at the surface contacting cover or baseplate 110, and the second contacts 108 provide the other of the resilient material or the rigid material at the surface contacting cover or baseplate 110. In this embodiment, the cover or baseplate is contacted by a rigid material on one side, and the resilient material on the other. The rigid material can be any suitable rigid material. In an embodiment, the rigid material is the same as the material used as the first shell 102 or the second shell 106. In an embodiment, the rigid material is polycarbonate, a polyolefin such as ultra-high molecular weight polyethylene, or ABS.

Second shell 106 forms another portion of container 100. When second shell 106 and first shell 102 are joined, the container 100 is configured to surround the cover or baseplate 110. The second shell 106 can be made of a rigid material, for example polycarbonate, a polyolefin such as ultra-high molecular weight polyethylene, or ABS. In an embodiment, the second shell 106 is made of the same material as first shell 102. Second shell 106 and first shell 102 can be joined by any suitable closure or combination thereof, such as latches, tabs, hinges, snap-fit features, magnetic surfaces, or the like. In the embodiment shown in FIG. 1, container 100 includes hinges 112 and latches 114 to secure first shell 102 and second shell 106 to one another.

Second shell 106 includes second contacts 108 as fixing features. The second contacts 108 positioned on shell 106 in positions configured to correspond to predetermined contact points on a second side of cover or baseplate 110, opposite the first side contacted by the first contacts 104. The second contacts 108 can be positioned to correspond to non-critical positions on the second side of the cover or baseplate 110. The second contacts 108 can include a rigid material. The second contacts 108 can include the material of the second shell 106. The second contacts 108 can include a resilient component such as any of the resilient components described above with respect to first contacts 104. In an embodiment, first contacts 104 and second contacts 108 combine to contact the reticle or baseplate 110 with a rigid material on one side and a resilient material on the opposite side. In an embodiment, first contacts 104 and second contacts 108 combine to contact the reticle or baseplate 110 with a rigid material on each of the opposing sides. In an embodiment, first contacts 104 and second contacts 108 combine to contact the reticle or baseplate with a resilient material on each of the opposing sides.

In an embodiment, some or all of the second contacts 108 and some or all of the first contacts 104 can interface with common features formed on cover or baseplate 110, such as through holes, the perimeter of the cover or baseplate 110, or the like. In an embodiment, the second contacts 108 are opposite first contacts 104 when container 100 is closed. In an embodiment, the first contacts 104 and second contacts 108 can contact one another when cover or baseplate 110 is located within container 100. In an embodiment, some or all of the first contacts 104 are contact one set of features on the first side of cover or baseplate 110, and some or all of the second contacts are configured to contact a different second set of features provided on the second side of cover or baseplate 110.

Contact between the first contacts 104, the cover or baseplate 110, and the second contacts 108 are such that the cover or baseplate 110 is retained within container 100 such that the cover or baseplate 110 is secured such that it will not move significantly in a direction in plane with one or both of first shell 102 and second shell 106. Minor temporary movements may occur depending on the use of resilient materials in first contacts 104 and/or second contacts 108 or due to wear on parts or variation within manufacturing tolerances for one or both of container 100 and cover or baseplate 110.

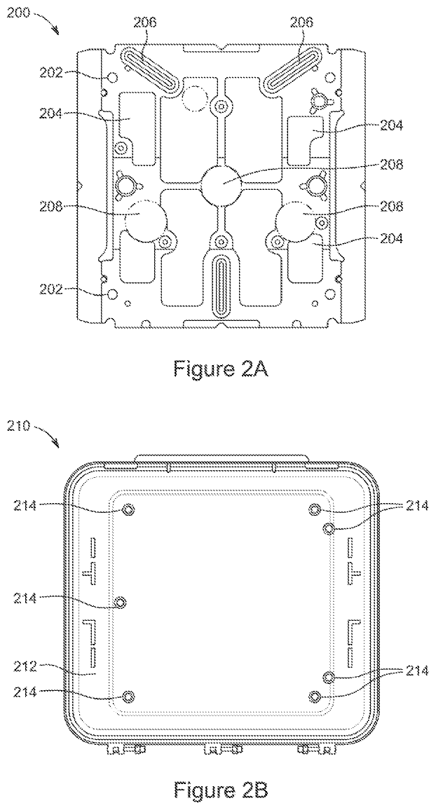

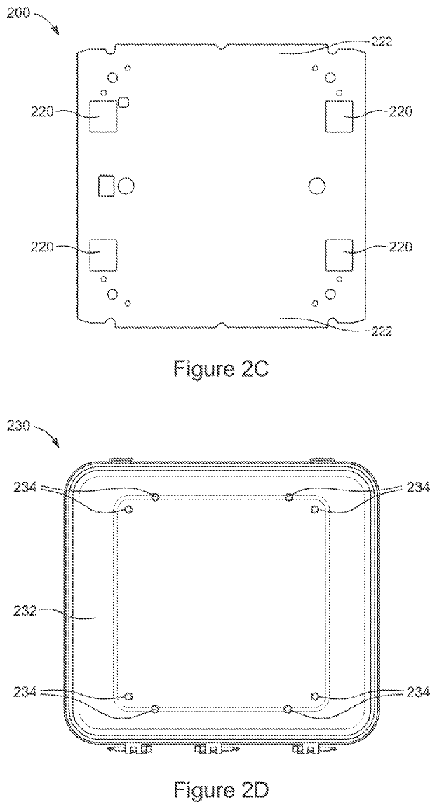

FIG. 2A shows a first side of a baseplate of a reticle pod to be stored in a container according to an embodiment. First side of baseplate 200 can be a side facing outwards when the reticle pod including baseplate 200 is assembled. First side of baseplate 200 includes safety catch holes 202, weight reduction pockets 204, and kinematic coupling features 206 such as kinematic coupling grooves. Any, some, or all of safety catch holes 202, weight reduction pockets 204, and kinematic coupling features 206 can be used as the points of first side of baseplate to be contacted by first shell contacts 214 as discussed below and shown in FIG. 2B. Reflector zones 208 can be provided on the first side of baseplate 200. The reflector zones 208 can be used to orient the baseplate during handling of a reticle.

FIG. 2B shows a first shell configured to be used on the first side of the baseplate of FIG. 2A. First shell 210 includes shell body 212 and a plurality of first shell contacts 214. The shell body 212 defines a portion of an internal space to contain baseplate 200. A plurality of first shell contacts 214 are distributed on a surface of the shell body 210 configured to face the first side of baseplate 200 when a container including first shell 210 and second shell 230 is assembled. The first shell contacts 214 can be any suitable configuration of contacts for contacting the baseplate 200, such as any of contacts 502, 602, 702, 802, or 902 as shown in FIGS. 5-9 and discussed below. The first shell contacts 214 can be positioned to correspond to the safety catch holes 202, weight reduction pockets 204, or kinematic coupling features 206 of the first side of baseplate 200. The first shell contacts can be positioned so as to avoid contact with the reflector zones 208 provided on the first side of baseplate 200.

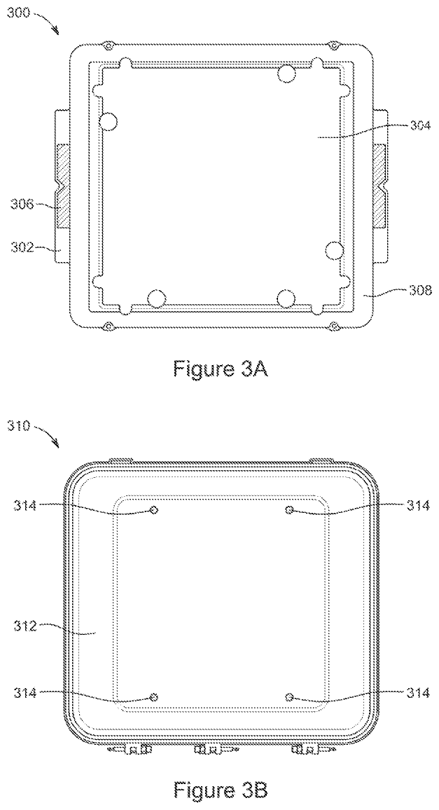

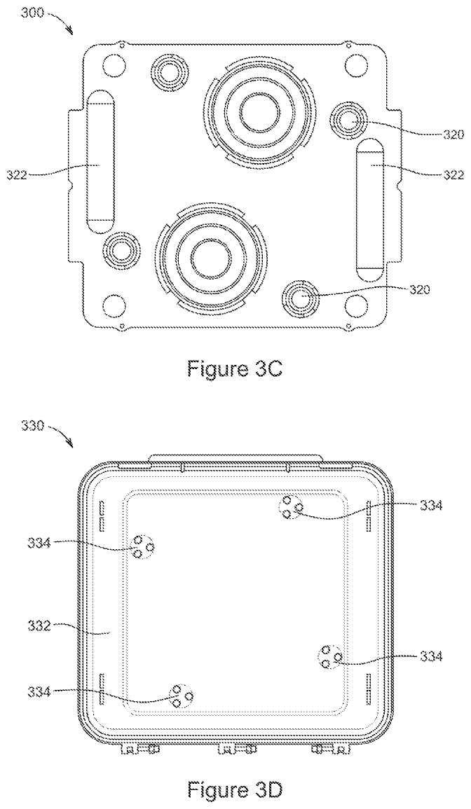

FIG. 2C shows a second side of the baseplate shown in FIG. 2A. Second side of baseplate 200 is a side of the baseplate 200 configured to face the reticle when the reticle pod including baseplate 200 is used to contain a reticle. The second side of baseplate 200 includes gripper pockets 220. The second side of baseplate also includes baseplate seal areas 222. The baseplate seal areas 222 are at positions where a cover, such as cover 300 discussed below and shown in FIGS. 3A-3D is in contact with the baseplate 200 when the reticle pod including baseplate 200 and cover 300 is assembled. The second side also includes an under-reticle space 224, located between reticle contacts 226 provided on the second side of baseplate 200.

FIG. 2D shows a second shell configured to be used on the second side of the baseplate of FIG. 2C. Second shell 230 includes second shell body 232 and second shell contacts 234. The second shell body defines another portion of an internal space to contain baseplate 200. The second shell contacts 234 can be any suitable configuration of contacts for contacting the baseplate 200, such as any of contacts 502, 602, 702, 802, or 902 as shown in FIGS. 5-9 and discussed below. The second shell contacts 234 can be positioned preferably to correspond to the gripper pockets 220 of the second side of baseplate 200. The second shell contacts 234 can be positioned such that they do not contact the seal areas 222 or under-reticle space 224 of the second side of baseplate 200. The seal areas 222 and under-reticle space 224 can be considered critical regions of baseplate 200. The criticality of these regions can be due to, for example, particulate generated in such areas having a high likelihood of affecting a reticle, or the visibility of the finish on the surfaces in the seal areas 222 and the under-reticle space 224.

FIG. 3A shows a first side of a cover of a reticle pod to be stored in a container according to an embodiment. First side of cover 300 is a side of cover 300 that faces a reticle when cover 300 is assembled with a baseplate such as baseplate 200 to form a reticle pod. The first side of cover 300 includes a flange 302. The first side of cover 300 further includes reticle relief 304, which defines a portion of the internal space of the reticle pod including cover 300. Flange 302 also includes reflector regions 306. First side of cover 300 further includes sealing areas 308. The cover seal areas 308 are areas configured to contact the baseplate such as baseplate 200 when the reticle pod including cover 300 is assembled. The cover seal areas 308 of the cover 300 can correspond to the baseplate seal areas 222 shown in FIG. 2C and described above.

FIG. 3B shows a first shell configured to be used on the first side of the cover of FIG. 3A. First shell 310 includes first shell body 312 and first shell contacts 314. First shell body 312 defines a portion of an internal space to contain cover 300. A plurality of first shell contacts 314 are distributed on a surface of the shell body 310 configured to face the first side of cover 300 when a container including first shell 310 and second shell 330 is assembled. The first shell contacts 314 can be positioned to correspond positions on the first side of cover 300 such as parts of flange 302 outside of the reflector regions 306. The first shell contacts 314 can be positioned such that they do not contact reticle relief 304, reflector regions 306, or cover seal areas 308 when the cover 300 is placed into the first shell 310.

FIG. 3C shows a second side of the cover shown in FIG. 3A. Second side of cover 300 faces outwards when cover 300 is assembled into a reticle pod, for example when combined with baseplate 200. Second side of cover 300 includes through holes 320. The through holes 320 can be insertion holes for features to be subsequently installed into cover 300. Second side of the cover 300 further includes weight reduction cutouts 322.

FIG. 3D shows a second shell configured to be used on the second side of the cover of FIG. 3C. Second shell 330 includes second shell body 332 and second shell contacts 334. Second shell body 332 defined another portion of the internal space to contain cover 300. Second shell contacts 334 are provided on a side of the shell body 332 configured to face the second side of cover 300 when cover 300 is located within the container formed by first shell 310 and second shell 330. The second shell contacts 334 can be located at positions corresponding to positions on the second side cover 300, for example the through holes 320 and/or the weight reduction cutouts 322.

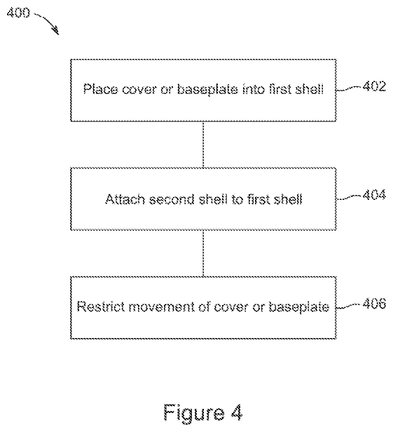

FIG. 4 shows a flowchart of a method according to an embodiment. Method 400 includes placing a cover or a baseplate of a reticle pod into a first shell of a container 402. The method 400 further includes joining a second shell of the container to the first shell 404. Method 400 also includes engagement of fixing features of the first and second shells restricting movement of the cover or baseplate 406.

A cover or a baseplate of a reticle pod is placed into a first shell of a container 402. The cover or baseplate can be either a cover or a baseplate, selected to correspond to the container including the first shell. The cover or baseplate can be placed into the first shell of the container at 402 such that a side of the cover or baseplate corresponding to the first shell faces the interior of the first shell, and such that fixing features of the first shell such as the first contacts 104 described above and shown in FIG. 1 interface with corresponding features on the cover or baseplate.

Joining a second shell of the container to the first shell 404. The second shell can be joined to the first shell at 404 by any suitable connection, for example by latching the second shell to the first shell, for example using latches 114 as described above and shown in FIG. 1. In an embodiment, the second shell can be pivoted about one or more hinges such as hinge 112 described above and shown in FIG. 1 to where it is joined to the first shell by the latch or other closure. The joining of the second shell to the first shell at 404 results in the first shell and the second shell forming an internal space containing the cover or baseplate placed into the first shell at 402. The joining of the second shell to the first shell at 404 subsequent to the cover or baseplate being placed into the first shell at 402 brings second fixing features on the second shell, such as second contacts 108 described above and shown in FIG. 1 engage with the second side of the reticle or baseplate.

Engagement of fixing features of the first and second shells restricting movement of the cover or baseplate 406. The movement that is restricted at 406 is movement that is in plane with at least one of the first shell or the second shell. The movement is restricted by contact of the cover or baseplate with the fixing features at predetermined locations of the cover or baseplate. The resistance to movement by the engagement at 406 can restrict movement due to shocks, for example if the container including the cover or baseplate is dropped, struck, or the like. The restriction of movement at 406 can reduce vibration of the cover or baseplate within the container. The restriction of movement can be prevention or reduction of movement. In an embodiment, the movement of the cover or baseplate can be restricted to an extent permitted by the flexibility of the materials used in the fixing features and manufacturing tolerances of the cover or baseplate and the respective fixing features. The fixing features can be engaging the cover or baseplate at predetermined locations such as the locations as identified above and shown in FIGS. 2A, 2C, 3A, and 3C.

FIG. 5 shows an interface of contacts of a container with a cover or baseplate being contained. In the embodiment of FIG. 5, shell 500 includes projection 502. Resilient tip 504 is provided over projection 502. The resilient tip 504 provides the surface contacting the contact feature 506 formed in the cover or baseplate 508. The resilient tip 504 can be connected to projection 502 by any suitable method, for example being press-fit over projection 502, interface of retention features formed on resilient tip 504 and/or projection 502, overmolding, adhesives, combinations thereof, or the like. Resilient tip 504 can be shaped to correspond to the shape of the contact feature 506, for example to engage with particular areas of the contact feature 506.

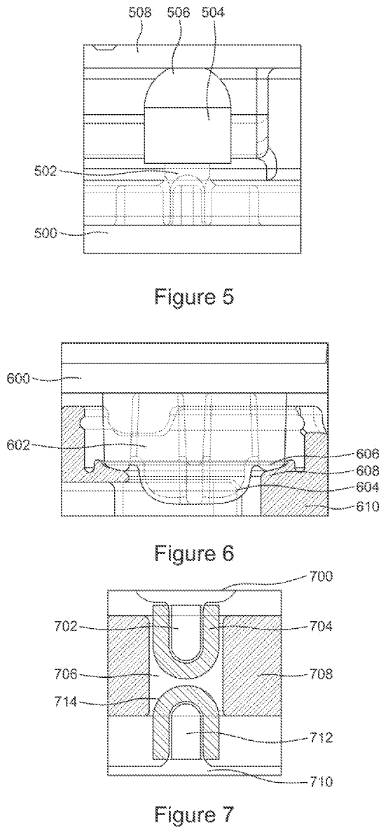

FIG. 6 shows another interface of contacts of a container with a cover or baseplate being contained. In the embodiment of FIG. 6, shell 600 includes projection 602 extending to rigid tip 604, with shoulder 606 also provided on projection 602. In an embodiment, projection 602 and rigid tip 604 are formed integrally with shell 600 and are composed of the same material as shell 600. Rigid tip 604 provides the surface contacting the contact feature 608 of cover or baseplate 610. The shoulder 606 can have a shape selected to correspond to the shape of contact feature 608, for example to engage with particular areas of the contact feature 608.

FIG. 7 shows another interface of contacts of a container with a cover or baseplate being contained. In the embodiment shown in FIG. 7, first shell 700 includes first projection 702, which is covered by first resilient tip 704. Resilient tip 704 extends into through hole 706 formed in the cover or baseplate 708. Second shell 710 includes second projection 712, which is covered by second resilient tip 714. The second resilient tip 714 also extends into through hole 706. The first resilient tip 704 and the second resilient tip 714 can contact one another within the through hole 706.

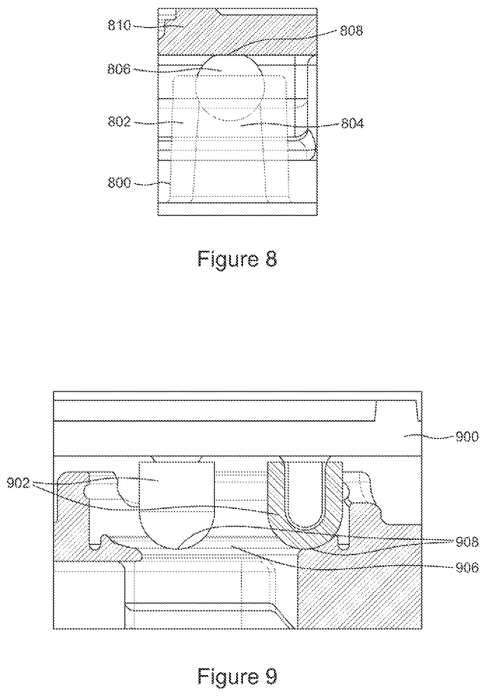

FIG. 8 shows another interface of contacts of a container with a cover or baseplate being contained. In the embodiment shown in FIG. 8, the shell 800 includes projection 802. Projection 802 includes a recess 804 formed in projection 802. Recess 804 can have any suitable shape. In an embodiment, recess 804 can be cylindrical. In an embodiment, recess 804 is conical or frustoconical in shape. Resilient insert 806 can be retained in recess 804. In an embodiment, resilient insert 806 can be press-fit into recess 804. In an embodiment, resilient insert 806 can be joined to projection 802 by any suitable features such as engagement features, adhesives, or the like. Resilient insert 806 includes a resilient material. Resilient insert 806 is configured to contact the contact feature 808 of cover or baseplate 810. In an embodiment, a portion of projection 802 can also contact the contact feature 808 of cover or baseplate 810.

FIG. 9 shows another interface of contacts of a container with a cover or baseplate being contained. In the embodiment shown in FIG. 9, the shell 900 provides a plurality of contacts 902. All of the plurality of contacts 902 interface with a single contact feature 904 of the cover or baseplate 906. Some or all of the contacts 902 can include a resilient material at an end 908 of each of contacts 902. The resilient material at end 908 can be applied over projections 902. The projections 902 can be formed integrally with shell 900. In an embodiment, some or all of the projections 902 can extend to ends 908 without resilient material being provided, thus providing rigid material at the surfaces interfacing contact feature 904 of cover or baseplate 906.

### ASPECTS

It is understood that any of aspects 1-9 can be combined with any of aspects 10-18.

Aspect 1. A container for a cover or a baseplate of a reticle pod, comprising:

a first shell comprising a plurality of first fixing features; and

a second shell comprising a plurality of second fixing features;

wherein:

the first shell and the second shell are configured to be joined together,

when the first shell and the second shell are joined together, the first shell and the second shell define an interior space, the interior space sized such that it can accommodate the cover or the baseplate of the reticle pod,

the first fixing features are configured to engage the cover or the baseplate of the reticle pod at first predetermined positions corresponding to first pod features provided on a first side of the cover or the baseplate of the reticle pod,

the second fixing features are configured to engage the cover or the baseplate of the reticle pod at second predetermined positions corresponding to second pod features provided on a second side of the cover or the baseplate of the reticle pod, and

when the first fixing features engage with the first pod features and the second fixing features engage with the second pod features, the engagement restricts movement of the cover or the baseplate of the reticle pod in plane with at least one of the first shell or the second shell.

Aspect 2. The container according to aspect 1, wherein at least one of the first fixing features or the second fixing features each include a resilient material.

Aspect 3. The container according to aspect 2, wherein the resilient material is a fluoroelastomer.

Aspect 4. The container according to any of aspects 1-3, wherein at least one of the first fixing features or the second fixing features each include a rigid material.

Aspect 5. The container according to aspect 4, wherein the rigid material is a same material as a body of the first shell or the second shell.

Aspect 6. The container according to any of aspects 1-5, wherein the container is for the cover of the reticle pod and at least some of the first predetermined positions and the second predetermined positions correspond to through holes of the cover of the reticle pod.

Aspect 7. The container according to any of aspects 1-6, wherein the container is for the baseplate of the reticle pod and at least one of the first predetermined positions or the second predetermined positions corresponds to a kinematic coupling groove of the baseplate of the reticle pod.

Aspect 8. The container according to any of aspects 1-7, wherein the first predetermined positions and the second predetermined positions correspond to non-functional locations of the cover or the baseplate of the reticle pod.

Aspect 9. The container according to any of aspects 1-8, wherein the first shell and the second shell each include polycarbonate or a polyolefin.

Aspect 10. A method of storing a cover or a baseplate of a reticle pod, comprising:

placing the cover or the baseplate of the reticle pod into a first shell of a container, the first shell including a plurality of first fixing features, wherein placing the cover or the baseplate of the reticle pod into the first shell includes engaging first pod features on a first side of the cover or the baseplate with the plurality of first fixing features; and

joining a second shell of the container to the first shell of the container, the second shell including second engagement features, where joining the second shell of the container to the first shell includes engaging second pod features on a second side of the cover or the baseplate with the second fixing features,

wherein the engagement of the first fixing features with the first pod features and the engagement of the second fixing features with the second pod features restrict movement of the cover or the baseplate of the reticle pod in plane with at least one of the first shell or the second shell.

Aspect 11. The method according to aspect 10, wherein at least one of the first fixing features or the second fixing features each include a resilient material.

Aspect 12. The method according to aspect 11, wherein the resilient material is a fluoroelastomer.

Aspect 13. The method according to any of aspects 10-12, wherein at least one of the first fixing features or the second fixing features each include a rigid material.

Aspect 14. The method according to aspect 13, wherein the rigid material is a same material as a body of the first shell or the second shell.

Aspect 15. The method according to any of aspects 10-14, wherein the cover or the baseplate being stored is the cover of the reticle pod and at least some of the first fixing features and the second fixing features engage with through holes formed in the cover of the reticle pod.

Aspect 16. The method according to any of aspects 10-15, wherein the cover or the baseplate being stored is the baseplate of the reticle pod and at least some of the first fixing features and the second fixing features engage with a kinematic coupling groove of the baseplate of the reticle pod.

Aspect 17. The method according to any of aspects 10-16, wherein the first fixing features and the second fixing features engage with non-functional locations of the cover or the baseplate of the reticle pod.

Aspect 18. The method according to any of aspects 10-17, wherein the first shell and the second shell each include polycarbonate or a polyolefin.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A container for a cover or a baseplate of a reticle pod, comprising:
a first shell comprising a plurality of first fixing features; and
a second shell comprising a plurality of second fixing features;
wherein:
the first shell and the second shell are configured to be joined together,
when the first shell and the second shell are joined together, the first shell and the second shell define an interior space, the interior space sized such that it can accommodate the cover or the baseplate of the reticle pod,
the first fixing features are configured to engage the cover or the baseplate of the reticle pod at first predetermined positions corresponding to first pod features provided on a first side of the cover or the baseplate of the reticle pod,
the second fixing features are configured to engage the cover or the baseplate of the reticle pod at second predetermined positions corresponding to second pod features provided on a second side of the cover or the baseplate of the reticle pod, and
when the first fixing features engage with the first pod features and the second fixing features engage with the second pod features, the engagement restricts movement of the cover or the baseplate of the reticle pod in plane with at least one of the first shell or the second shell.

2. The container of claim 1, wherein at least one of the first fixing features or the second fixing features each include a resilient material.

3. The container of claim 2, wherein the resilient material is a fluoroelastomer.

4. The container of claim 1, wherein at least one of the first fixing features or the second fixing features each include a rigid material.

5. The container of claim 4, wherein the rigid material is a same material as a body of the first shell or the second shell.

6. The container of claim 1, wherein the container is for the cover of the reticle pod and at least some of the first predetermined positions and the second predetermined positions correspond to through holes of the cover of the reticle pod.

7. The container of claim 1, wherein the container is for the baseplate of the reticle pod and at least one of the first predetermined positions or the second predetermined positions corresponds to a kinematic coupling groove of the baseplate of the reticle pod.

8. The container of claim 1, wherein the first predetermined positions and the second predetermined positions correspond to non-functional locations of the cover or the baseplate of the reticle pod.

9. The container of claim 1, wherein the first shell and the second shell each include polycarbonate or a polyolefin.

10. A method of storing a cover or a baseplate of a reticle pod, comprising:
placing the cover or the baseplate of the reticle pod into a first shell of a container, the first shell including a plurality of first fixing features, wherein placing the cover or the baseplate of the reticle pod into the first shell includes engaging first pod features on a first side of the cover or the baseplate with the plurality of first fixing features; and
joining a second shell of the container to the first shell of the container, the second shell including second engagement features, where joining the second shell of the container to the first shell includes engaging second pod features on a second side of the cover or the baseplate with the second fixing features,
wherein the engagement of the first fixing features with the first pod features and the engagement of the second fixing features with the second pod features restrict movement of the cover or the baseplate of the reticle pod in plane with at least one of the first shell or the second shell.

11. The method of claim 10, wherein at least one of the first fixing features or the second fixing features each include a resilient material.

12. The method of claim 11, wherein the resilient material is a fluoroelastomer.

13. The method of claim 10, wherein at least one of the first fixing features or the second fixing features each include a rigid material.

14. The method of claim 13, wherein the rigid material is a same material as a body of the first shell or the second shell.

15. The method of claim 10, wherein the cover or the baseplate being stored is the cover of the reticle pod and at least some of the first fixing features and the second fixing features engage with through holes formed in the cover of the reticle pod.

16. The method of claim 10, wherein the cover or the baseplate being stored is the baseplate of the reticle pod and at least some of the first fixing features and the second fixing features engage with a kinematic coupling groove of the baseplate of the reticle pod.

17. The method of claim 10, wherein the first fixing features and the second fixing features engage with non-functional locations of the cover or the baseplate of the reticle pod.

18. The method of claim 10, wherein the first shell and the second shell each include polycarbonate or a polyolefin.
